(19) United States
(12) Patent Application Publication
(10) Pub. No.: US 2015/0053262 A1
(43) Pub. Date: Feb. 26, 2015

(54) TRANSPARENT SOLAR CELL AND REAR-REFLECTIVE TRANSPARENT SOLAR CELL MODULE HAVING THE SAME

(71) Applicant: Electronics and Telecommunications Research Institute, Daejeon (KR)

(72) Inventors: JungWook LIM, Daejeon (KR); Sun Jin YUN, Daejeon (KR)

(73) Assignee: Electronics and Telecommunications Research Institute, Daejeon (KR)

(21) Appl. No.: 14/327,990

(22) Filed: Jul. 10, 2014

(30) Foreign Application Priority Data
Aug. 26, 2013 (KR) 10-2013-0101259
Jan. 9, 2014 (KR) 10-2014-0002921

(51) Int. Cl. H01L 31/052; H01L 31/0224

(52) U.S. Cl. CPC H01L 31/0527; H01L 31/022466
USPC 136/256

(57) ABSTRACT

Provided are a transparent solar cell and a rear-reflective transparent solar cell module having the same. The transparent solar cell includes a transparent substrate, a first transparent electrode on the transparent substrate, a light absorption layer on the first transparent electrode, a re-absorption enhancing layer on the light absorption layer, and a second transparent electrode on the re-absorption enhancing layer.

### CROSS-REFERENCE TO RELATED APPLICATIONS

This U.S. non-provisional patent application claims priority under 35 U.S.C. §119 of Korean Patent Application Nos. 10-2013-0101259, filed on Aug. 26, 2013 and 10-2014-0002921, filed on Jan. 9, 2014, the entire contents of which are hereby incorporated by reference.

### BACKGROUND OF THE INVENTION

The present invention disclosed herein relates to a solar cell and a module having the same, and more particularly, to a transparent solar cell and a rear-reflective transparent solar cell module having the same.

Currently, silicon thin film solar cells have a limitation in that they have lower energy efficiency than crystalline silicon solar cells. However, the silicon thin film solar cells have advantages in that they can be manufactured through a low temperature process, be formed on various substrates, and also have a thin thickness. Thus, the silicon thin film solar cells can be used as transparent solar cells. In particular, it is now believed that fully-transmissive transparent solar cells are more effective technology than pattern-type transparent solar cells having metal grids because the fully-transmissive transparent solar cells can realize various colors and be applicable for windows of buildings.

Although the transparent solar cells that give a though to the application of the windows are being focused on a dye-sensitized solar cell, it needs more technical efforts due to efficiency reduction in large area and limitations in stability and life cycle. In existing transparent solar cells, it has been focused on developing technology for improving transmittance and efficiency. In addition, various methods for improving efficiency are being proposed. For example, the dye-sensitized solar cells which are capable of absorbing solar light by using opposite electrode plates and both transparent electrodes regardless of an angle of the sun have been suggested. In this case, however, there are limitations in that the dye-sensitized solar cells have low stability due to electrolyte in the due-sensitized structure, and additional components and costs are required due to the opposite electrode plates when compared to the existing dye-sensitized solar cells.

In case of organic solar cells, like the above-described structure, a solar cell structure that is capable of generating power by receiving light through both sides thereof has been suggested. However, this technology needs to secure safety and is being focused on improvement in efficiency rather than transmittance.

According to the present invention, when a transmissive transparent solar cell of which the whole area transmits light is manufactured by using a thin film silicon or a silicon germanium solar cell, a reflection blind or a front reflection board is provided on front and rear surfaces of the solar cell so that the transmitted light may be re-absorbed to improve efficiency. Therefore, the transparent solar cell may significantly improve in efficiency without additional costs.

### SUMMARY OF THE INVENTION

The present invention provides a transparent solar cell having high durability and productivity and a rear-reflective transparent solar cell module having the same.

Embodiments of the inventive concept provide transparent solar cells including: a transparent substrate; a first transparent electrode on the transparent substrate; a light absorption layer on the first transparent electrode; a re-absorption enhancing layer on the light absorption layer; and a second transparent electrode on the re-absorption enhancing layer.

In some embodiments, the re-absorption enhancing layer may have a refractive index less than that of the light absorption layer.

In other embodiments, the re-absorption enhancing layer may include metal oxide such as zinc oxide (ZnO), aluminum oxide (Al₂O₃), titanium dioxide (TiO₂), aluminum tin oxide (AlTiO), zirconium dioxide (ZrO₂), or copper oxide (Cu₂O).

In still other embodiments, the re-absorption enhancing layer may have an energy bandgap higher than the light absorption layer.

In even other embodiments, the re-absorption enhancing layer may include a silicon oxide film, a silicon nitride film, or a silicon carbide film, or a silicon germanium thin film.

In other embodiments of the inventive concept, rear-reflective transparent solar cell modules include: a transparent solar cell; and a lower reflection unit below the transparent solar cell, wherein the transparent solar cell includes: a transparent substrate; a first transparent electrode on the transparent substrate; a light absorption layer on the first transparent electrode; a re-absorption enhancing layer on the light absorption layer; and a second transparent electrode on the re-absorption enhancing layer, the second transparent electrode being adjacent to the lower reflection unit.

In some embodiments, the lower reflection unit may include a reflection blind.

In other embodiments, the lower reflection unit may include a lower reflection board.

In still other embodiments, the rear-reflective transparent solar cell modules may further include an upper reflection unit disposed above the transparent solar cell that is opposite to the lower reflection unit, the upper reflection unit being disposed adjacent to the transparent substrate.

In even other embodiments, the upper reflection unit may include an upper reflection board.

In yet other embodiments, the upper reflection unit may include: reflection folders disposed below the transparent substrate to reflect solar light, that is provided to the rear-reflective transparent solar cell, into the transparent substrate, each of the reflection folders having a plurality of inclined reflection surfaces of which reflection angles are adjusted by the folding; and a plurality of first reflection sheets connected to both ends of the inclined reflection surfaces of the reflection folder to re-reflect the solar light, that is reflected by the rear-reflection unit, into the rear-reflective transparent solar cell.

In further embodiments, the upper reflection unit may include first elastic threads disposed between the inclined reflection surfaces of the reflection folder, each of the first elastic threads being connected to a center of the first reflection sheet to fix the first reflection sheet within the folder when the folder is folded and unfolded.

In still further embodiments, the lower reflection unit may include: non-reflection folders disposed above the second transparent electrode; and a plurality of second reflection sheets connected to both ends of each of the non-reflection folder to reflect the solar light into the rear-reflective transparent solar cell.

In even further embodiments, the lower reflection unit may include second elastic threads disposed between the inclined reflection surfaces of the non-reflection folder, each of the second elastic threads being connected to a center of the second reflection sheet to fix the second reflection sheet within the non-reflection folder when the folder is folded and unfolded

### BRIEF DESCRIPTION OF THE DRAWINGS

The accompanying drawings are included to provide a further understanding of the present invention, and are incorporated in and constitute a part of this specification. The drawings illustrate exemplary embodiments of the inventive concept and, together with the description, serve to explain principles of the present invention. In the drawings:

FIGS. 1 and 2 are plan and cross-sectional views of a rear-reflective transparent solar cell module according to a first embodiment of the inventive concept, respectively;

FIG. 3 is a graph illustrating a voltage-current curve of the transparent solar cell;

FIG. 4 is a view of a rear-reflective transparent solar cell module according to a first application example of the present invention;

FIG. 5 is a view of a rear-reflective transparent solar cell module according to a second embodiment of the inventive concept; and

FIGS. 6 and 7 are views illustrating a rear-reflective transparent solar cell module according to a second application example of the present invention.

FIGS. 8 and 9 are views illustrating a rear-reflective transparent solar cell module according to a third application example of the present invention.

### DETAILED DESCRIPTION OF PREFERRED EMBODIMENTS

Hereinafter, preferred embodiments of the inventive concept will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

In the following description, the technical terms are used only for explain a specific exemplary embodiment while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components. Since preferred embodiments are provided below, the order of the reference numerals given in the description is not limited thereto.

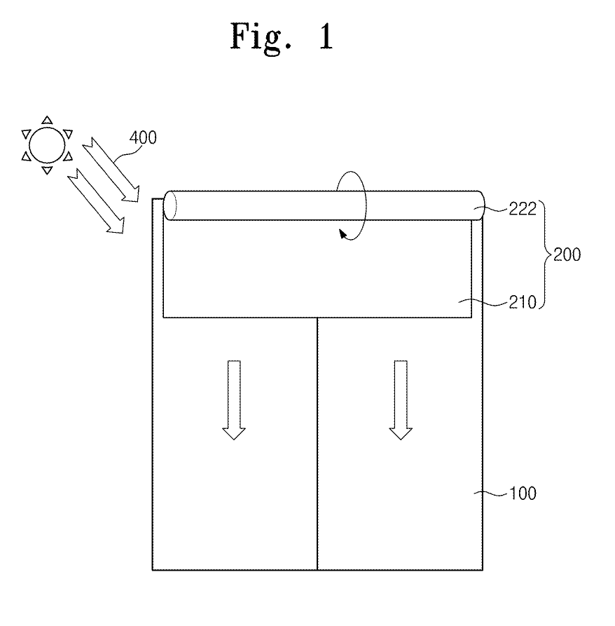

FIGS. 1 and 2 are plan and cross-sectional views of a rear-reflective transparent solar cell module according to a first embodiment of the inventive concept, respectively.

Referring to FIGS. 1 and 2, the rear-reflective transparent solar cell module according to the first embodiment of the inventive concept may include a transparent solar cell 100 and a rear reflection unit 200.

The transparent solar cell 100 may have a characteristic in which a portion of solar light is absorbed, and the rest is transmitted. The transparent solar cell 100 may include a transparent substrate 110, a first transparent electrode 120, a light absorption layer 130, a re-absorption enhancing layer, and a second transparent electrode 150.

The transparent substrate 110 may include glass or transparent plastic.

The first transparent electrode 120 may be disposed on the transparent substrate 110. A lower transparent electrode may include indium tin oxide (ITO) or indium zinc oxide (IZO).

The light absorption layer 130 may absorb solar light 400 to generate electricity. The light absorption layer 130 may include silicon (amorphous, microcrystal) or a silicon compound such as silicon germanium. The light absorption layer 130 has a thickness of about 50 nm to 300 nm.

The re-absorption enhancing layer 140 may increase re-absorption of light 500 reflected by a reflection blind 210. According to an example, the re-absorption enhancing layer 140 may have a refractive index less than that of the light absorption layer 130. The solar light 400 that is incident between the re-absorption enhancing layer 140 and the light absorption layer 130 may be mostly absorbed into the light absorption layer 130. Also, the reflected light 500 provided in the re-absorption enhancing layer 140 may be mostly absorbed into the light absorption layer 130. For example, the re-absorption enhancing layer 140 may include a silicon germanium thin film and metal oxide such as zinc oxide (ZnO), aluminum oxide (Al₂O₃), titanium dioxide (TiO₂), aluminum tin oxide (AlTiO), zirconium dioxide (ZrO₂), or copper oxide (Cu₂O). According to an example, the re-absorption enhancing layer 140 may have an energy band gap higher than that of the light absorption layer 130. For example, the re-absorption enhancing layer 140 may include a silicon oxide film, a silicon nitride film, or a silicon carbide film. The re-absorption enhancing layer 140 may have a thickness of about 5 nm to 200 nm. The re-absorption enhancing layer 140 may be disposed on the second transparent electrode 150.

The rear reflection unit 200 may re-reflect light that is transmitted through the transparent solar cell 100. According to an example, the rear reflection unit 200 may include the reflection blind 210. The reflection blind 210 may be disposed above the second transparent electrode 150. The reflection blind 210 may be wound around a roller 222. The reflection blind 210 may be unwound from the roller 222. The reflection blind 210 may not directly contact the transparent solar cell 100. The reflection blind 210 may be spaced apart a short distance from the transparent solar cell 100. The reflection blind 210 may include a mirror applied to a cloth, a paper, or a thin film, a metal, or a multilayered high reflective film (an insulation material). The reflection blind 210 may act as a shading unit for blocking the excessively strong solar light 400 and improving generating efficiency.

Therefore, the rear-reflective transparent solar cell module according to the first embodiment of the inventive concept may be used for sunroofs of vehicles or widows of buildings.

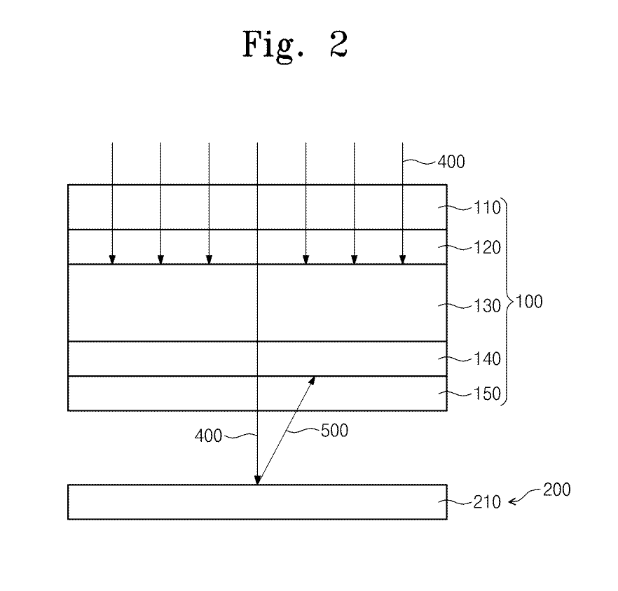

FIG. 3 is a graph illustrating a voltage-current curve of the transparent solar cell.

Referring to FIGS. 1 to 3, the transparent solar cell 100 may have a higher voltage-current value when the reflection blind 210 is installed. The reflection blind 210 may increase a light absorption rate of the transparent solar cell 100. Also, the reflection blind 210 may increase a short-circuit current of the transparent solar cell 100, an open-circuit voltage, and a fill factor (FF). Here, an abscissa represents a voltage, and an ordinate represents a current.

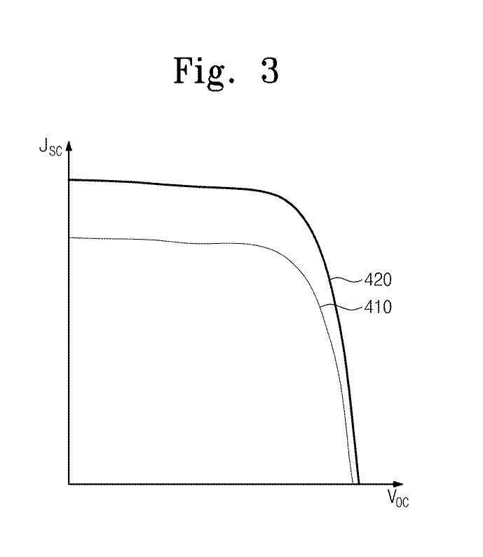

FIG. 4 is a view of a rear-reflective transparent solar cell module according to a first application example of the present invention.

Referring to FIG. 4, the rear-reflective transparent solar cell module according to the first application example of the present invention may include the rear reflection unit 200 of a rear reflection board 220. The rear reflection board 220 may be disposed above the second transparent electrode 150. The solar light 400 may be reflected by the rear reflection board 220 and then re-absorbed into the transparent solar cell 100. In the first application example, the reflection blind 210 of the first embodiment is replaced with the rear reflection board 220.

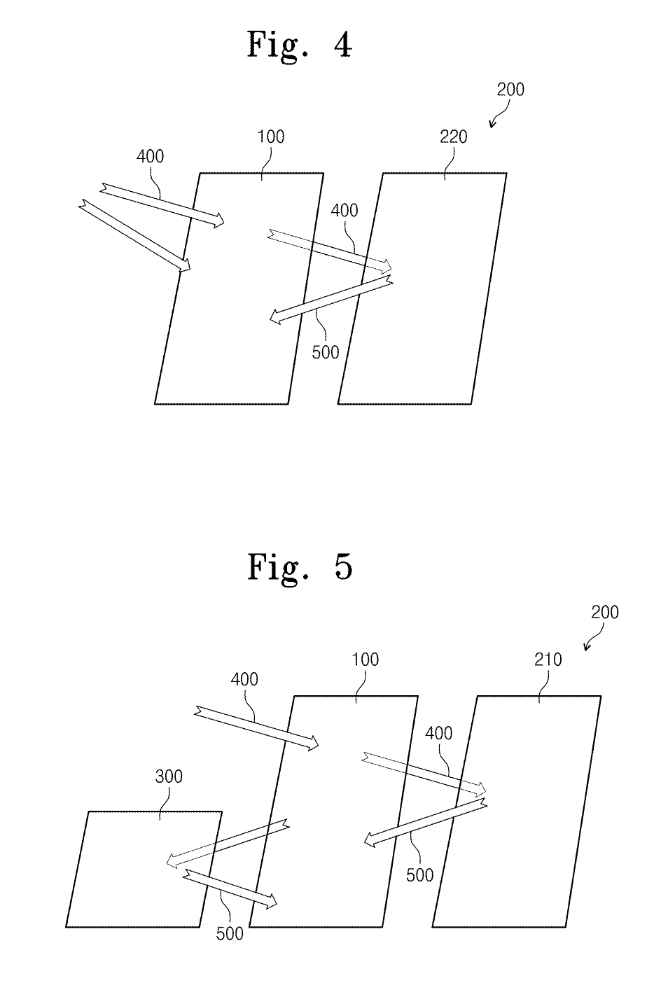

FIG. 5 is a view of a rear-reflective transparent solar cell module according to a second embodiment of the inventive concept.

Referring to FIG. 5, the rear-reflective transparent solar cell module according to the second embodiment of the inventive concept may include a front reflection unit 300. The front reflection unit 300 may be disposed above a front surface of a transparent solar cell 100, which is opposite to a reflection blind 210. The front reflection unit 300 may be an upper reflection unit. The front reflection unit 300 may re-reflect reflection light 500 provided from the rear reflection blind 210 to allow the reflection light 500 to be absorbed into the transparent solar cell 100. The front reflection unit 300 may additionally improve power generating efficiency of the transparent solar cell 100. According to an example, the front reflection unit 300 may include a reflection board. According to the second embodiment, the front reflection unit 300 is provided above the front surface of the transparent solar cell 100 according to the first embodiment.

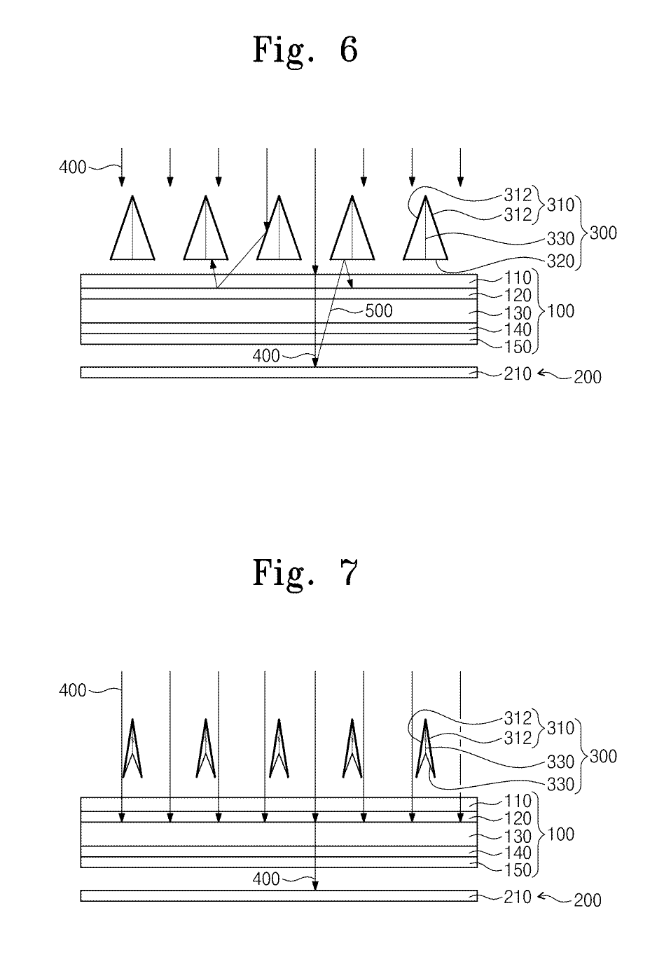

FIGS. 6 and 7 are views illustrating a rear-reflective transparent solar cell module according to a second application example of the present invention.

Referring to FIGS. 6 and 7, the rear-reflective transparent solar cell module according to the second application example may include a front reflection unit 300 in which reflection folders 310, first reflection sheets 320, and first elastic threads 330 are provided.

Each of the reflection folders 310 may be folded and spread in a direction of the transparent solar cell 100. The reflection folder 310 may have a plurality of inclined reflection surfaces 312. The inclined reflection surfaces 312 may guide solar light 400 to the transparent solar cell 100. The solar light 400 may be reflected by the inclined reflection surfaces 312 of the reflection folder 310 and then be incident into the transparent solar cell 100. The solar light 400 may be directly incident into the transparent solar cell 100 without passing through the reflection folder 310 when the reflection folder 310 is unfolded.

The first reflection sheets 320 may be connected to both edges of each of the reflection folders 310. Each of the first reflection sheets 320 may be disposed between the reflection folder 310 and the transparent solar cell 100. The reflection light 500 may be provided from the reflection blind 210 of the rear reflection unit 200. The first reflection sheet 320 may re-reflect the reflection light 500 to the transparent solar cell 100.

Each of the first elastic threads 330 may be connected from a center of the reflection folder 310 to a center of the first reflection sheet 320. The first elastic thread 330 may draw the first reflection sheet 320 into the reflection folder 310 when the reflection folder 310 is folded. The first elastic thread 330 may define a folding direction of the first reflection sheet 320.

In the second application example, the front reflection unit 300 according to the second embodiment is constituted by the reflection folders 310, the first reflection sheets 320, and the first elastic threads 330.

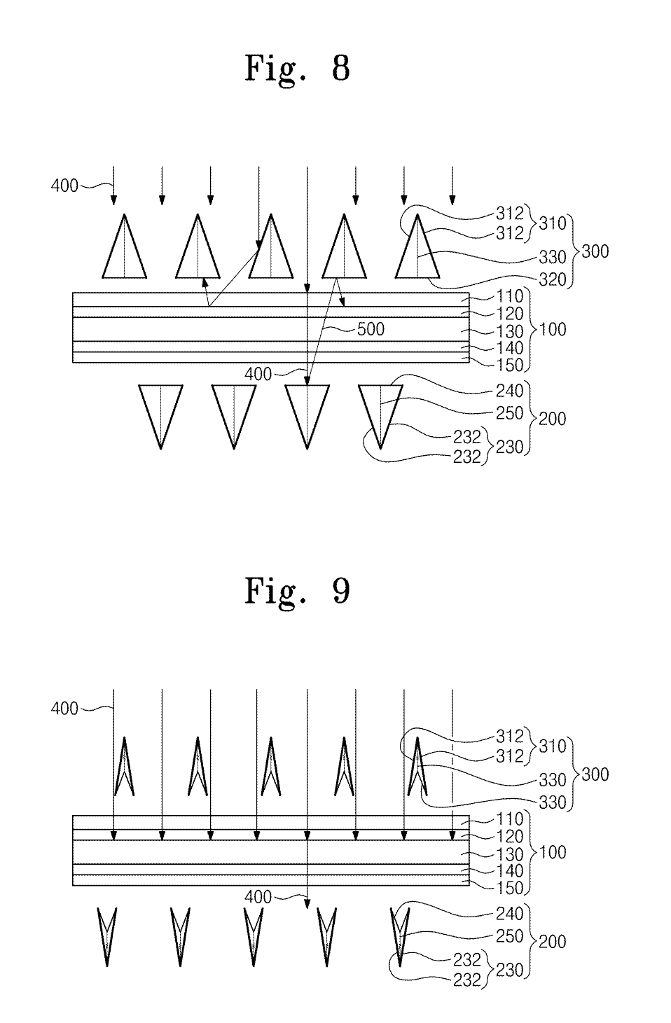

FIGS. 8 and 9 are views illustrating a rear-reflective transparent solar cell module according to a third application example of the present invention.

Referring to FIGS. 8 and 9, the rear-reflective transparent solar cell module according to the third application example may include a rear reflection unit 200 in which non-reflection folders 230, second reflection sheets 240, and second elastic threads 250 are provided.

Each of the non-reflection folders 230 may be folded and spread in a direction of the transparent solar cell 100. The reflection folder 230 may have a plurality of inclined non-reflection surfaces 232.

Each of the second reflection sheets 240 may be connected to both edges of each of the non-reflection folders 230. The non-reflection sheet 230 may be disposed between the non-reflection folder 230 and the transparent solar cell 100.

The solar light 400 may be transmitted through the transparent solar cell 100. The non-reflection sheet 230 may reflect the solar light 400 to the transparent solar cell 100 when the non-reflection folder 230 is unfolded. The solar light 400 may proceed without passing through the rear reflection unit 200 when the non-reflection folder 310 is folded.

Each of the second elastic threads 250 may be connected from a center of the non-reflection folder 230 to a center of the second reflection sheet 240. The second elastic thread 250 may draw the second reflection sheet 240 into the non-reflection folder 230 when the non-reflection folder 230 is folded. The second elastic thread 250 may define a folding direction of the second reflection sheet 240.

In the third application example, the rear reflection unit 200 according to the second application example is constituted by the non-reflection folders 230, the second reflection sheets 240, and the second elastic threads 250.

As described above, the rear-reflective transparent solar cell module according to the embodiment of the inventive concept may include the transparent solar cell and the rear reflection unit. The transparent solar cell may include the light absorption layer and the re-absorption enhancing layer. The rear reflection unit may be disposed on a rear surface of the transparent solar cell. The re-absorption enhancing layer may allow the light absorption layer to improve the absorption efficiency of the light reflected from the rear reflection unit.

While this invention has been particularly shown and described with reference to preferred embodiments thereof, it will be understood by those skilled in the art that various changes in form and details may be made therein without departing from the spirit and scope of the invention as defined by the appended claims. Therefore, the preferred embodiments should be considered in descriptive sense only and not for purposes of limitation.

What is claimed is:

1. A transparent solar cell comprising:
a transparent substrate;
a first transparent electrode on the transparent substrate;
a light absorption layer on the first transparent electrode;
a re-absorption enhancing layer on the light absorption layer; and
a second transparent electrode on the re-absorption enhancing layer.

2. The transparent solar cell of claim 1, wherein the re-absorption enhancing layer has a refractive index less than that of the light absorption layer.

3. The transparent solar cell of claim 1, wherein the re-absorption enhancing layer comprises metal oxide such as zinc oxide (ZnO), aluminum oxide (Al₂O₃), titanium dioxide (TiO₂), aluminum tin oxide (AlTiO), zirconium dioxide (ZrO₂), or copper oxide (Cu₂O).

4. The transparent solar cell of claim 1, wherein the re-absorption enhancing layer has an energy bandgap higher than the light absorption layer.

5. The transparent solar cell of claim 1, wherein the re-absorption enhancing layer comprises a silicon oxide film, a silicon nitride film, or a silicon carbide film, or a silicon germanium thin film.

6. A rear-reflective transparent solar cell module comprising:
a transparent solar cell; and
a lower reflection unit below the transparent solar cell,
wherein the transparent solar cell comprises:
a transparent substrate;
a first transparent electrode on the transparent substrate;
a light absorption layer on the first transparent electrode;
a re-absorption enhancing layer on the light absorption layer; and
a second transparent electrode on the re-absorption enhancing layer, the second transparent electrode being adjacent to the lower reflection unit.

7. The rear-reflective transparent solar cell module of claim 6, wherein the lower reflection unit comprises a reflection blind.

8. The rear-reflective transparent solar cell module of claim 6, wherein the lower reflection unit comprises a lower reflection board.

9. The rear-reflective transparent solar cell module of claim 6, further comprising an upper reflection unit disposed above the transparent solar cell that is opposite to the lower reflection unit, the upper reflection unit being disposed adjacent to the transparent substrate.

10. The rear-reflective transparent solar cell module of claim 9, wherein the upper reflection unit comprises an upper reflection board.

11. The rear-reflective transparent solar cell module of claim 9, wherein the upper reflection unit comprises:
reflection folders disposed below the transparent substrate to reflect solar light, that is provided to the rear-reflective transparent solar cell, into the transparent substrate, each of the reflection folders having a plurality of inclined reflection surfaces of which reflection angles are adjusted by the folding; and
a plurality of first reflection sheets connected to both ends of the inclined reflection surfaces of the reflection folder to re-reflect the solar light, that is reflected by the rear-reflection unit, into the rear-reflective transparent solar cell.

12. The rear-reflective transparent solar cell module of claim 11, wherein the upper reflection unit comprises first elastic threads disposed between the inclined reflection surfaces of the reflection folder, each of the first elastic threads being connected to a center of the first reflection sheet to fix the first reflection sheet within the folder when the folder is folded and unfolded.

13. The rear-reflective transparent solar cell module of claim 6, wherein the lower reflection unit comprises:
non-reflection folders disposed above the second transparent electrode; and
a plurality of second reflection sheets connected to both ends of each of the non-reflection folder to reflect the solar light into the rear-reflective transparent solar cell.

14. The rear-reflective transparent solar cell module of claim 13, wherein the lower reflection unit comprises second elastic threads disposed between the inclined reflection surfaces of the non-reflection folder, each of the second elastic threads being connected to a center of the second reflection sheet to fix the second reflection sheet within the non-reflection folder when the folder is folded and unfolded.
